(19) United States
(12) Patent Application Publication
(10) Pub. No.: US 2023/0328909 A1
(43) Pub. Date: Oct. 12, 2023

(54) ELECTRONIC DEVICE COVER HAVING LAYERED STRUCTURE AND METHOD FOR MANUFACTURING SAME

(71) Applicant: SAMSUNG ELECTRONICS CO., LTD., Suwon-si (KR)

(72) Inventors: Sookyu LEE, Suwon-si (KR); Jaewoong LIM, Suwon-si (KR)

(73) Assignee: SAMSUNG ELECTRONICS CO., LTD., Suwon-si (KR)

(21) Appl. No.: 18/209,191

(22) Filed: Jun. 13, 2023

Related U.S. Application Data
(63) Continuation of application No. PCT/KR2022/000358, filed on Jan. 10, 2022.

(30) Foreign Application Priority Data
Jan. 22, 2021 (KR) 10-2021-0009537

(51) Int. Cl. H05K 5/03; B44C 3/02

(52) U.S. Cl. CPC H05K 5/03; B44C 3/02

(57) ABSTRACT

This application relates to an electronic device cover having a layered structure and a method for manufacturing the same. An embodiment may include a substrate including magnesium, a first chemical conversion-treated layer formed on the substrate, a bending supplement layer formed on the first chemical conversion-treated layer, a color layer formed on the bending supplement layer, and an ultraviolet molding layer formed on the color layer. Various other embodiments are possible.

### CROSS-REFERENCE TO RELATED APPLICATION(S)

This application is a Bypass Continuation Application of PCT International Application No. PCT/KR2022/000358, filed on Jan. 10, 2022, which is based on and claims priority to Korean Patent Application No. 10-2021-0009537, filed on Jan. 22, 2021, in the Korean Intellectual Property Office, the disclosure of which are incorporated by reference herein in their entireties.

### BACKGROUND

### 1. Field

The disclosure relates to an electronic device cover having a layered structure and a method of manufacturing the same.

### 2. Description of Related Art

An electronic device may be a device that performs a specific function according to a loaded program, such as a home appliance, an electronic note, a portable multimedia player, a mobile communication terminal, a tablet personal computer (PC), a video/audio device, a desktop/laptop computer, a vehicle navigation system, and the like. For example, such electronic devices may output stored information as sound or images. Along with an increase in the integration level of electronic devices and the increasing popularity of ultra-high-speed, large-capacity wireless communication, various functions have recently been loaded into a single electronic device, such as a mobile communication terminal. For example, an entertainment function such as gaming, a multimedia function such as music/video play, a communication and security function for mobile banking, a scheduling function, and an electronic wallet function, as well as a communication function, have been integrated into a single electronic device.

An electronic device includes a cover which can be formed of various materials. The cover of the electronic device may protect internal components of the electronic device from an external impact. In addition, the cover may be manufactured to be easily carried by a user, and can be made to be aesthetically pleasing to the user.

Since magnesium (Mg) is lighter than aluminum (Al) by 33% or more, magnesium is suitable for use in portable general-purpose electronic devices. Magnesium (Mg) is easily oxidized, and it is difficult to perform surface treatment (e.g., anodizing) for forming a film, and accordingly a painting method using, for example, thermal spray coating, has been mainly used to use magnesium for an electronic device cover.

### SUMMARY

According to various embodiments, an electronic device cover having a layered structure in which multiple layers are formed on a substrate containing magnesium may be provided.

According to various embodiments, an electronic device cover that may form multiple layers on a substrate containing magnesium to prevent oxidation of magnesium and that may have various colors and patterns may be provided.

According to an embodiment, an electronic device cover having a layered structure may include a substrate including magnesium, a first chemical conversion-treated layer formed on the substrate, a bending supplement layer formed on the first chemical conversion-treated layer, a color layer formed on the bending supplement layer, and an ultraviolet (UV) molding layer formed on the color layer.

According to an embodiment, a method of manufacturing an electronic device cover having a layered structure may include a step of preparing a substrate including magnesium, a step of forming a first chemical conversion-treated layer on the substrate, a step of forming a bending supplement layer on the first chemical conversion-treated layer, a step of forming a color layer on the bending supplement layer, a step of forming a UV molding layer on the color layer, and a step of curing the UV molding layer.

According to various embodiments, an electronic device cover having a layered structure in which multiple layers are formed on a substrate containing magnesium may be provided.

According to various embodiments, an electronic device cover that may form multiple layers on a substrate containing magnesium to prevent oxidation of magnesium and that may have various colors and patterns may be provided.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a block diagram illustrating an electronic device in a network environment according to various embodiments;

FIG. 2 is a cross-sectional view of an electronic device cover having a layered structure according to various embodiments;

FIG. 3 is a cross-sectional view of an electronic device cover having a layered structure according to various embodiments;

FIG. 4 is a cross-sectional view of an electronic device cover having a layered structure according to various embodiments;

FIG. 5 is a cross-sectional view of an electronic device cover having a layered structure according to various embodiments;

FIG. 6 is a cross-sectional view of an electronic device cover having a layered structure according to various embodiments;

FIG. 7 is a flowchart illustrating a method of manufacturing an electronic device cover according to an embodiment;

FIG. 8 is a flowchart illustrating a method of manufacturing an electronic device cover according to an embodiment;

FIG. 9 is a flowchart illustrating a method of manufacturing an electronic device cover according to an embodiment; and

FIG. 10 is a flowchart illustrating a method of manufacturing an electronic device cover according to an embodiment.

### DETAILED DESCRIPTION

Hereinafter, embodiments will be described in detail with reference to the accompanying drawings. When describing the embodiments with reference to the accompanying drawings, like reference numerals refer to like components and a repeated description related thereto will be omitted.

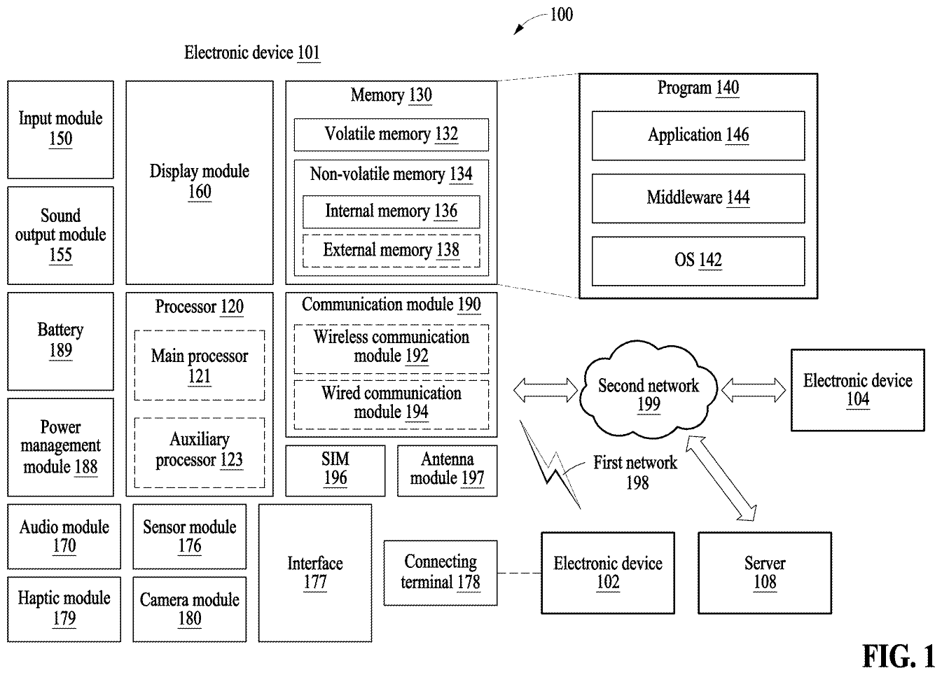

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or communicate with at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, a memory 130, an input module 150, a sound output module 155, a display module 160, an audio module 170, and a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one (e.g., the connecting terminal 178) of the above components may be omitted from the electronic device 101. In some embodiments, one or more other components may be added to the electronic device 101. In some embodiments, some (e.g., the sensor module 176, the camera module 180, or the antenna module 197) of the components may be integrated as a single component (e.g., the display module 160).

The processor 120 may execute, for example, software (e.g., a program 140) to control at least one component (e.g., a hardware or software component) of the electronic device 101 connected to the processor 120, and may perform various data processing or computation. According to an embodiment, as at least a part of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. The processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a part of the main processor 121.

The auxiliary processor 123 may control at least some functions or states related to at least one (e.g., the display module 160, the sensor module 176, or the communication module 190) of the components of the electronic device 101, instead of the main processor 121. The auxiliary processor 123 may control at least some functions or states while the main processor 121 is in an inactive (e.g., sleep) state or along with the main processor 121 while the main processor 121 is in an active state (e.g., executing an application). According to an embodiment, the auxiliary processor 123 (e.g., an ISP or a CP) may be implemented as a portion of another component (e.g., the camera module 180 or the communication module 190) that is functionally related to the auxiliary processor 123. According to an embodiment, the auxiliary processor 123 (e.g., an NPU) may include a hardware structure specified for artificial intelligence model processing. An artificial intelligence model may be generated by machine learning. Such machine learning may be performed by, for example, the electronic device 101 in which an artificial intelligence model is executed, or performed via a separate server (e.g., the server 108). Machine learning algorithms may include, but are not limited to, for example, supervised learning, unsupervised learning, semi-supervised learning, or reinforcement learning. The artificial intelligence model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited thereto. The artificial intelligence model may additionally or alternatively include a software structure other than the hardware structure.

The memory 130 may store a variety of data used by at least one component (e.g., the processor 120 or the sensor module 176) of the electronic device 101. The data may include, for example, software (e.g., the program 140) and input data or output data for a command related thereto. The memory 130 may include the volatile memory 132 or the non-volatile memory 134.

The program 140 may be stored as software in the memory 130, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen), or a combination of these components.

The sound output module 155 may output a sound signal to the outside of the electronic device 101. The sound output module 155 may include, for example, a speaker or a receiver. The speaker may be used for general purposes, such as playing multimedia or playing record. The receiver may be used to receive an incoming call. According to an embodiment, the receiver may be integrated with the speaker, or implemented separately from the speaker.

The display module 160 may visually provide information to the outside (e.g., a user) of the electronic device 101. The display module 160 may include, for example, a display, a hologram device, or a projector and control circuitry to control a corresponding one of the display, the hologram device, and the projector. According to an embodiment, the display module 160 may include a touch sensor adapted to sense a touch, and/or a pressure sensor adapted to measure an intensity of a force incurred by the touch.

The audio module 170 may convert a sound into an electric signal and vice versa. According to an embodiment, the audio module 170 may obtain the sound via the input module 150 or output the sound via the sound output module 155 or an external electronic device (e.g., an electronic device 102 such as a speaker or headphones) directly or wirelessly connected to the electronic device 101.

The sensor module 176 may detect an operational state (e.g., power or temperature) of the electronic device 101 or an environmental state (e.g., a state of a user) external to the electronic device 101, and generate an electric signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., by wire) or wirelessly. According to an embodiment, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). According to an embodiment, the connecting terminal 178 may include, for example, one of an HDMI connector, a USB connector, an SD card connector, or an audio connector (e.g., a headphone connector).

The haptic module 179 may convert an electric signal into a mechanical stimulus (e.g., a vibration or a movement) or an electrical stimulus which may be recognized by a user via his or her tactile sensation or kinesthetic sensation. According to an embodiment, the haptic module 179 may include, for example, a motor, a piezoelectric element, or an electric stimulator.

The camera module 180 may capture a still image and moving images. According to an embodiment, the camera module 180 may include one or more lenses, image sensors, ISPs, or flashes.

The power management module 188 may manage power supplied to the electronic device 101. According to an embodiment, the power management module 188 may be implemented as, for example, at least a part of a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108). The communication module 190 may further perform communication via the established communication channel. The communication module 190 may include one or more CPs that are operable independently of the processor 120 (e.g., an AP) and that support a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). The communication module 192 may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., a LAN or a wide area network (WAN))). The various types of communication modules of the communication module 192 may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mmWave band) to achieve a high data transmission rate. The wireless communication module 192 may support various technologies for securing performance on a high-frequency band, such as, e.g., beamforming, massive multiple-input and multiple-output (MIMO), full dimensional MIMO (FD-MIMO), an array antenna, analog beam-forming, or a large scale antenna. The wireless communication module 192 may support various requirements specified by any of the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal to or from the outside (e.g., the external electronic device) of the electronic device 101. The antenna module 197 may also transmit or receive power to or from the outside of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in a communication network, such as either the first network 198 or the second network 199, may be selected by the communication module 190. The signal or power may be transmitted or received between the communication module 190 and the external electronic device via the at least one selected antenna. According to an embodiment, another component (e.g., a radio frequency integrated circuit (RFIC)) other than the radiating element may be additionally formed as a part of the antenna module 197.

According to various embodiments, the antenna module 197 may form a mmWave antenna module. According to an embodiment, the mmWave antenna module may include a PCB, an RFIC disposed on a first surface (e.g., a bottom surface) of the PCB or adjacent to the first surface and capable of supporting a designated high-frequency band (e.g., a mmWave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of the same type as or a different type from the electronic device 101. According to an embodiment, all or some of operations to be executed by the electronic device 101 may be executed at one or more external electronic devices (e.g., the external electronic devices 102 and 104, and the server 108). For example, if the electronic device 101 needs to perform a function or a service automatically, or in response to a request from a user or another device, the electronic device 101, instead of, or in addition to, executing the function or the service, may request one or more external electronic devices to perform at least part of the function or the service. The one or more external electronic devices receiving the request may perform the at least part of the function or the service requested, or an additional function or an additional service related to the request, and may transfer an outcome of the performing to the electronic device 101. The electronic device 101 may provide the outcome, either with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or MEC. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., a smart home, a smart city, a smart car, or healthcare) based on 5G communication technology or IoT-related technology.

Hereinafter, an electronic device cover forming an exterior of the electronic device 101 will be further described through various embodiments.

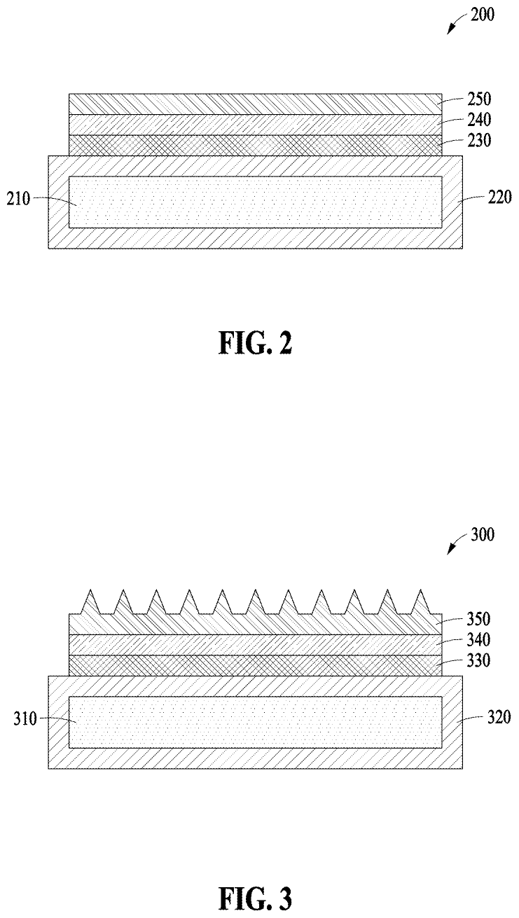

FIG. 2 is a cross-sectional view of an electronic device cover having a layered structure according to various embodiments.

According to various embodiments, an electronic device may include a cover. A cover member may include an alloy containing magnesium as a main material, and may provide an aesthetically pleasing effect through a metallic texture expressed outward. Since an electronic device cover containing magnesium has a relatively low specific gravity in comparison to aluminum, a lightweight electronic device that is easy to carry may be provided.

Referring to FIG. 2, an electronic device cover 200 may include a substrate 210 including magnesium, a first chemical conversion-treated layer 220, a bending supplement layer 230, a color layer 240, and an ultraviolet (UV) molding layer 250.

According to an embodiment, the first chemical conversion-treated layer 220 may be disposed on the substrate 210. The first chemical conversion-treated layer 220 may be formed to cover a portion of the substrate 210 or may be formed to cover the entire surface of the substrate 210.

According to an embodiment, the first chemical conversion-treated layer 220 may include a magnesium oxide film. The first chemical conversion-treated layer 220 may include at least one selected from the group of magnesium chromate, magnesium oxide, aluminum oxide, silicon oxide, and titanium oxide. The first chemical conversion-treated layer 220 may be formed to cover a portion or all portions of the substrate 210 formed of easily oxidizable magnesium, and may protect the substrate 210 to prevent the substrate 210 from contacting water and oxygen.

According to an embodiment, the bending supplement layer 230 may be disposed on the first chemical conversion-treated layer 220. The bending supplemental layer 230 may be formed on the first chemical conversion-treated layer 220. The bending supplement layer 230 may not be cracked, for example, broken or split, in a step of deforming a shape, which may be included in a process of manufacturing the electronic device cover 200. The bending supplement layer 230 may be positioned between the first chemical conversion-treated layer 220 and the color layer 240. When the color layer 240 is formed directly on the first chemical conversion-treated layer 220, the color layer 240 may easily fall due to insufficient adhesion. Therefore, the bending supplement layer 230 may be formed on the first chemical conversion-treated layer 220 to supplement adhesion.

According to an embodiment, the bending supplement layer 230 may include an epoxy-based polymer.

According to an embodiment, the color layer 240 may be disposed on the bending supplement layer 230. The color layer 240 may be formed on the bending supplement layer 230. The color layer 240 may form the overall color of the electronic device cover 200 and appeal to an aesthetic sense of consumers.

According to an embodiment, the UV molding layer 250 may be disposed on the color layer 240. The UV molding layer 250 may be formed on the color layer 240. The UV molding layer 250 may be formed on an outermost portion of the electronic device cover 200, and the shape of the UV molding layer 250 may determine a reflection state of incident light.

According to an embodiment, the UV molding layer 250 may include a monomer having two functional groups. The UV molding layer 250 may include a UV-curable monomer having two functional groups. The UV molding layer 250 may include at least one bifunctional monomer selected from the group of hexanediol diacrylate (HDDA), tripropylene glycol diacrylate (TPGDA), hydroxypropyl acrylate (HPA), and 2-hydroxyethyl methacrylate (2-HEMA). The UV molding layer 250 may include at least one acrylate-based monomer selected from the group of hexanediol diacrylate (HDDA), tripropylene glycol diacrylate (TPGDA), hydroxypropyl acrylate (HPA), and 2-hydroxyethyl methacrylate (2-HEMA). The bifunctional monomer may not be cracked even though the shape is deformed, due to excellent workability and flexibility after being cured, in comparison to monomers having at least three functional groups.

According to an embodiment, the UV molding layer 250 may have a pencil hardness of F or higher. The pencil hardness may be obtained by measuring resistance to a mark or defect on a surface when the surface is pressed with a pencil lead under a load of 1 kg_{f}, and may be measured according to ASTM D 3363. The pencil hardness may be measured from 9B (softest) to 9H (hardest). Here, the closer to 9B, the lower the pencil hardness, and the closer to 9H, the higher the pencil hardness.

According to an embodiment, the bending supplement layer 230 and the UV molding layer 250 may be crack-free. The bending supplement layer 230 and the UV molding layer 250 may be stretched or contracted while being deformed in the step of deforming the shape in the process of manufacturing the electronic device cover 200, and may not be cracked due to the deformation. When defects occur in the bending supplement layer and the UV molding layer, oxygen, and water may contact the substrate 210 containing magnesium so that magnesium may be oxidized. The bending supplement layer 230 and the UV molding layer 250 may require flexibility so that a defect may not occur even though deformation is applied.

According to an embodiment, the bending supplement layer 230 and the UV molding layer 250 may be crack-free. The presence or absence of cracks may be determined by whether cracks are visually identified under a light source of 1,000 lux. When cracks occur in the bending supplement layer 230 and the UV molding layer 250, the substrate 210 may be corroded in a reliability test through deposition such as salt spray, impact resistance, hot water resistance, and the like.

FIG. 3 is a cross-sectional view of an electronic device cover having a layered structure according to various embodiments.

Referring to FIG. 3, an electronic device cover 300 may include a substrate 310 (e.g., the substrate 210 of FIG. 2) including magnesium, a first chemical conversion-treated layer 320 (e.g., the first chemical conversion-treated layer 220 of FIG. 2), a bending supplement layer 330 (e.g., the bending supplement layer 230 of FIG. 2), a color layer 340 (e.g., the color layer 240 of FIG. 2), and a UV molding layer 350.

Referring to FIG. 3, at least one area of the UV molding layer 350 may include a pattern.

According to an embodiment, the UV molding layer 350 may further include a spire-shaped pattern on a surface thereof.

Referring to FIGS. 2 and 3, when the UV molding layer 250 and 350 is flat, light incident on the UV molding layer 250 and 350 may be specularly reflected, and otherwise, light incident on the UV molding layer 350 may be diffusely reflected. A state of the reflected light may be determined according to a shape of a pattern formed on the surface of the UV molding layer, which may determine whether the electronic device cover is glossy. When the UV molding layer 250 and 350 is flat, the incident light may be specularly reflected so that the electronic device cover 200 may be glossy. Light incident on the UV molding layer 350 in which a pattern is formed may be diffusely reflected so that the electronic device cover 300 may be matte.

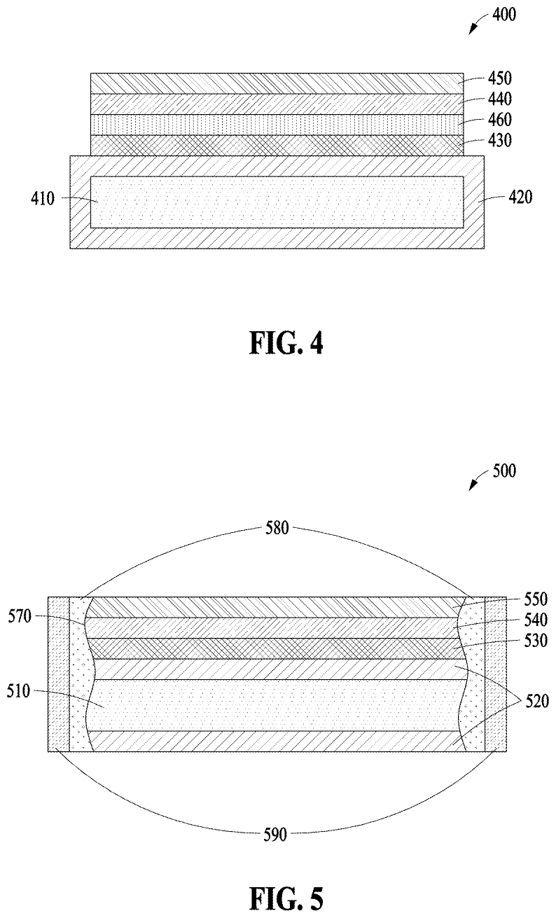

FIG. 4 is a cross-sectional view of an electronic device cover having a layered structure according to various embodiments.

Referring to FIG. 4, an electronic device cover 400 may include a substrate 410 (e.g., the substrate 210 of FIG. 2) including magnesium, a first chemical conversion-treated layer 420 (e.g., the first chemical conversion-treated layer 220 of FIG. 2), a bending supplement layer 430 (e.g., the bending supplement layer 230 of FIG. 2), a metal deposition layer 460, a color layer 440 (e.g., the color layer 240 of FIG. 2), and a UV molding layer 450 (e.g., the UV molding layer 250 of FIG. 2).

According to an embodiment, the metal deposition layer 460 may be disposed on the bending supplement layer 430. The metal deposition layer 460 may be disposed between the bending supplement layer 430 and the color layer 440. The layers may be formed on the layer from which they are disposed. The metal deposition layer 460 may include at least one metal selected from the group of tin (Sn), indium (In), aluminum (Al), and titanium (Ti). The metal deposition layer 460 may impart a metallic texture to the electronic device cover 400 so that a user may be provided with an aesthetically pleasing effect while using an electronic device.

FIG. 5 is a cross-sectional view of an electronic device cover having a layered structure according to various embodiments.

Referring to FIG. 5, an electronic device cover 500 may include a substrate 510 (e.g., the substrate 210 of FIG. 2) including magnesium, a first chemical conversion-treated layer 520 (e.g., the first chemical conversion-treated layer 220 of FIG. 2), a bending supplement layer 530 (e.g., the bending supplement layer 230 of FIG. 2), a color layer 540 (e.g., the color layer 240 of FIG. 2), and a UV molding layer 550 (e.g., the UV molding layer 250 of FIG. 2).

Referring to FIG. 5, the electronic device cover 500 may further include a cut portion 570, a second chemical conversion-treated layer 580, and an electrodeposition coating layer 590.

According to an embodiment, a cutting step may be performed on the electronic device cover 500 to form a cut portion. To meet specifications of various electronic devices, the substrate 510 may be cut in consideration of the size thereof. Here, the substrate 510 may be exposed to contact the outside, to form the cut portion 570. The cut portion 570 may be formed to contact at least a portion of the substrate 510, the first chemical conversion-treated layer 520, the bending supplement layer 530, the color layer 540, and the UV molding layer 550. The second chemical conversion-treated layer 580 may be formed on the cut portion 570 to cover the cut portion 570. The second chemical conversion-treated layer 580 may protect the substrate 510 to prevent the substrate 510 from contacting the outside, and may prevent oxidation in advance.

According to an embodiment, the second chemical conversion-treated layer 580 may include zirconium. The second chemical conversion-treated layer 580 may have a transparent color, and may not contaminate colors of the first chemical conversion-treated layer 520 (the first chemical conversion-treated layer 220 of FIG. 2), the color layer 540 (the color layer 240 of FIG. 2) or the UV molding layer 550 (the UV molding layer 250 of FIG. 2). The second chemical conversion-treated layer 580, which includes zirconium, may conduct electricity and may be suitable for electrodeposition coating.

According to an embodiment, the electrodeposition coating layer 590 may be formed on the second chemical conversion-treated layer 580. The electrodeposition coating layer 590 may include an epoxy-based or acrylic-based electrodeposition paint. The electrodeposition coating layer 590 may protect the second chemical conversion-treated layer 580 from contamination outside of the cover 600 and may be uniformly formed with a predetermined thickness (e.g., a thickness of 10 μm to 20 μm).

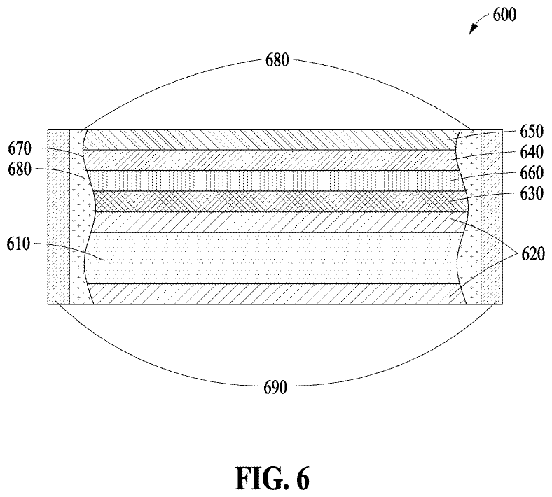

FIG. 6 is a cross-sectional view of an electronic device cover having a layered structure according to various embodiments.

Referring to FIG. 6, an electronic device cover 600 may include a substrate 610 (e.g., the substrate 210 of FIG. 2) including magnesium, a first chemical conversion-treated layer 620 (e.g., the first chemical conversion-treated layer 220 of FIG. 2), a bending supplement layer 630 (e.g., the bending supplement layer 230 of FIG. 2), a metal deposition layer 660 (e.g., the metal deposition layer 460 of FIG. 4), a color layer 640 (e.g., the color layer 240 of FIG. 2), and a UV molding layer 650 (e.g., the UV molding layer 250 of FIG. 2).

Referring to FIG. 6, the electronic device cover 600 may further include a cut portion 670, a second chemical conversion-treated layer 680, and an electrodeposition coating layer 690.

According to an embodiment, the metal deposition layer 660 may be formed on the bending supplement layer 630. The metal deposition layer 660 may be formed between the bending supplement layer 630 and the color layer 640. The metal deposition layer 660 may include at least one metal selected from the group of tin (Sn), indium (In), aluminum (Al), and titanium (Ti). The metal deposition layer 660 may impart a metallic texture to the electronic device cover 600 so that a user may be provided with an aesthetically pleasing effect while using an electronic device.

According to an embodiment, a cutting step may be performed on the electronic device cover 600 to form a cut portion. To meet specifications of various electronic devices, the substrate 610 may be cut in consideration of the size thereof. Here, the substrate 610 may be exposed to contact the outside, to form the cut portion 670. The cut portion 670 may be formed to contact at least a portion of the substrate 610, the first chemical conversion-treated layer 620, the bending supplement layer 630, the metal deposition layer 660, the color layer 640, and the UV molding layer 650. The second chemical conversion-treated layer 680 may be formed on the cut portion 670 to cover the cut portion 670. The second chemical conversion-treated layer 680 may protect the substrate 610 to prevent the substrate 610 from contacting the outside, and may prevent oxidation in advance.

According to an embodiment, the second chemical conversion-treated layer 680 may include zirconium. The second chemical conversion-treated layer 680 may have a transparent color, and may not contaminate colors of the first chemical conversion-treated layer 620 (the first chemical conversion-treated layer 220 of FIG. 2), the color layer 640 (the color layer 240 of FIG. 2) or the UV molding layer 650 (the UV molding layer 250 of FIG. 2). The second chemical conversion-treated layer 680, which includes zirconium, may conduct electricity and may be suitable for electrodeposition coating.

According to an embodiment, the electrodeposition coating layer 690 may be formed on the second chemical conversion-treated layer 680. The electrodeposition coating layer 690 may include an epoxy-based or acrylic-based electrodeposition paint. The electrodeposition coating layer 690 may protect the second chemical conversion-treated layer 680 from the outside and may be uniformly formed with a predetermined thickness (e.g., a thickness of 10 μm to 20 μm).

According to an embodiment, the bending supplement layer (e.g., the bending supplement layer 230 of FIG. 2) may include an epoxy-based polymer.

An electronic device cover having a layered structure according to an embodiment may further include a metal deposition layer (e.g., the metal deposition layer 460 of FIG. 4) formed between the bending supplement layer (e.g., the bending supplement layer 430 of FIG. 4) and the color layer (e.g., the color layer 440 of FIG. 4).

According to an embodiment, the metal deposition layer (e.g., the metal deposition layer 460 of FIG. 4) may include at least one metal selected from the group of tin (Sn), indium (In), aluminum (Al), and titanium (Ti).

According to an embodiment, the UV molding layer (e.g., the UV molding layer 250 of FIG. 2) may include at least one bifunctional monomer selected from the group of HDDA, TPGDA, HPA, and 2-HEMA.

According to an embodiment, the UV molding layer (e.g., the UV molding layer 250 of FIG. 2) may have hardness of a pencil hardness of F or higher.

According to an embodiment, the first chemical conversion-treated layer (e.g., the first chemical conversion-treated layer 220 of FIG. 2) may include at least one selected from the group of magnesium chromate, magnesium oxide, aluminum oxide, silicon oxide, and titanium oxide.

According to an embodiment, the bending supplement layer (e.g., the bending supplement layer 230 of FIG. 2) and the UV molding layer (e.g., the UV molding layer 250 of FIG. 2) may be crack-free.

According to an embodiment, at least one area of the UV molding layer (e.g., the UV molding layer 250 of FIG. 2) may include a pattern.

The electronic device cover having the layered structure according to an embodiment may further include a cut portion (e.g., the cutout portion 570 of FIG. 5), a second chemical conversion-treated layer (e.g., the second chemical conversion-treated layer 580 of FIG. 5) formed on the cut portion, and an electrodeposition coating layer (e.g., the electrodeposition coating layer 590 of FIG. 5) formed on the second chemical conversion-treated layer.

According to an embodiment, the second chemical conversion-treated layer (e.g., the second chemical conversion-treated layer 580 of FIG. 5) may include zirconium.

According to an embodiment, the electrodeposition coating layer (e.g., the electrodeposition coating layer 590 of FIG. 5) may be formed with a thickness of 10 μm to 20 μM.

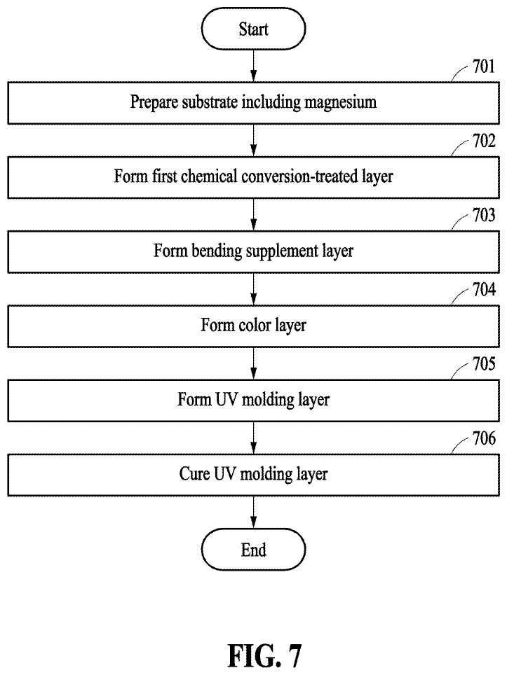

FIG. 7 is a flowchart illustrating a method of manufacturing an electronic device cover according to an embodiment.

Referring to FIG. 7, the method of manufacturing the electronic device cover may include step 701 of preparing a substrate including magnesium, step 702 of forming a first chemical conversion-treated layer, step 703 of forming a bending supplement layer, step 704 of forming a color layer, step 705 of forming a UV molding layer, and step 706 of curing the UV molding layer.

According to an embodiment, the substrate may be prepared through casting molding, press molding, or CNC molding. The substrate may include a general magnesium series or magnesium-lithium (Mg—Li) alloy. In an example, the substrate may include at least one selected from the group of AZ31B, AZ91, and AZ91D as the general magnesium series.

According to an embodiment, in step 702 of forming the first chemical conversion-treated layer, the first chemical conversion-treated layer may be formed on the substrate. The first chemical conversion-treated layer may be formed to cover a portion of the substrate, and a step of forming the first chemical conversion-treated layer to cover the entire surface of the substrate may be performed. Step 702 of forming the first chemical conversion-treated layer may be performed using a chromate compound including at least one selected from the group of sodium chromate (Na₂CrO₄), potassium chromate (K₂CrO₄), ammonium chromate ((NH₄)₂CrO₄), calcium chromate (CaCrO₄), zinc chromate (ZnCrO₄), sodium dichromate (Na₂Cr₂O₇), potassium dichromate (K₂Cr₂O₇), and ammonium dichromate ((NH₄)₂Cr₂O₇), or using micro arc oxidation (MAO).

According to an embodiment, in step 703 of forming the bending supplement layer, the bending supplement layer may be formed on the first chemical conversion-treated layer. The bending supplement layer may include an epoxy-based polymer. The bending supplement layer including the epoxy-based polymer may be formed on the first chemical conversion-treated layer through spray coating.

According to an embodiment, in step 704 of forming the color layer, the color layer may be formed on the bending supplement layer. The color layer may be formed on the bending supplement layer by spray-coating with colored paint.

According to an embodiment, in step 705 of forming the UV molding layer, the UV molding layer may be formed on the color layer. Step 705 of forming the UV molding layer may include forming a pattern.

According to an embodiment, step 705 of forming the UV molding layer 705 may include a step (not shown) of applying a UV-curable resin onto the color layer and a step (not shown) of pressing the UV-curable resin using a stamp on which a pattern is formed. A pattern opposite to the pattern may be formed on the UV-curable resin by the pattern formed on the stamp. When the UV-curable resin is pressed using a stamp on which an embossed or engraved pattern is formed, a pattern opposite to the pattern may be formed on the UV-curable resin.

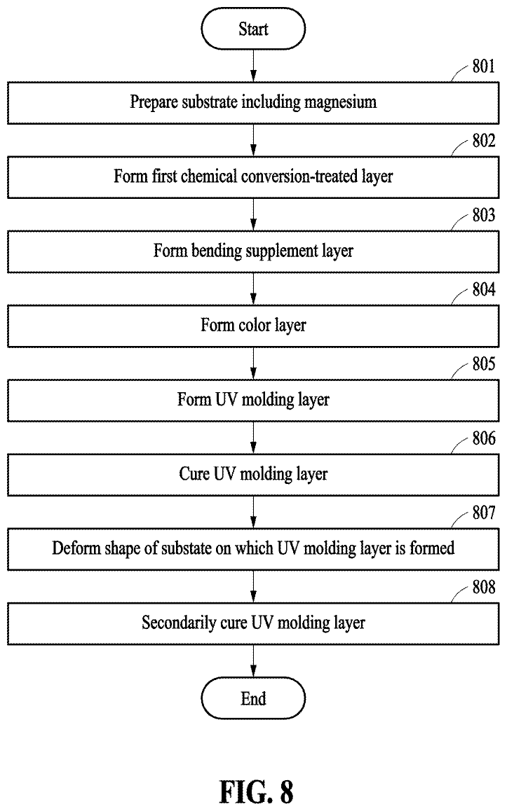

FIG. 8 is a flowchart illustrating a method of manufacturing an electronic device cover according to an embodiment.

Referring to FIG. 8, the method of manufacturing the electronic device cover may include step 801 of preparing a substrate including magnesium (step 701 of preparing the substrate in FIG. 7), step 802 of forming a first chemical conversion-treated layer (step 702 of forming the first chemical conversion-treated layer in FIG. 7), step 803 of forming a bending supplement layer (step 703 of forming the bending supplement layer in FIG. 7), step 804 of forming a color layer (step 704 of forming the color layer in FIG. 7), step 805 of forming a UV molding layer (step 705 of forming the UV molding layer in FIG. 7), step 806 of curing the UV molding layer (step 706 of curing the UV molding layer in FIG. 7), step 807 of deforming the shape of the substrate on which the UV molding layer is formed, and step 808 of secondarily curing (re-curing) the UV molding layer.

According to an embodiment, in step 807, the substrate may be bent by dividing the bending of the substrate into at least three operations so that a radius of curvature is less than 1.0 mm. When the substrate is abruptly bent so that the radius of curvature is less than 1.0 mm, defects may occur in the substrate, the first chemical conversion-treated layer, the bending supplement layer, the color layer, or the UV molding layer. Thus, the substrate may be bent by dividing the bending of the substrate into several operations. A stabilization step may be performed between deformation steps.

According to an embodiment, step 807 may be performed around a reference line spaced apart by a distance of 3 mm or greater from an outermost periphery of the substrate. A side surface of the substrate having a shape of a sheet may be referred to as an outermost periphery. If deformation is performed in an area of 3 mm or less from the outermost periphery of the substrate, defects may occur in any of the first chemical conversion-treated layer, the bending supplement layer, the color layer, or the UV molding layer. The reference line spaced apart by a sufficient distance (e.g., 3 mm or greater) may become deformed.

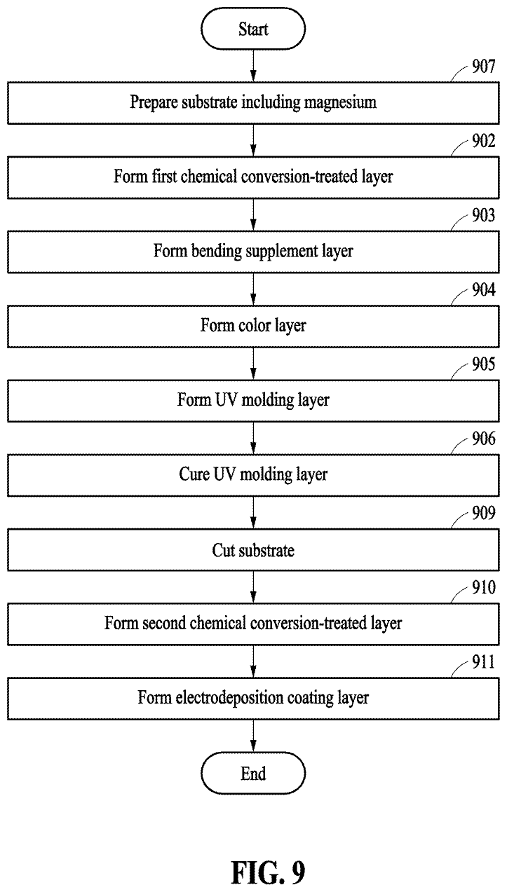

FIG. 9 is a flowchart illustrating a method of manufacturing an electronic device cover according to an embodiment.

Referring to FIG. 9, the method of manufacturing the electronic device cover may include step 901 of preparing a substrate including magnesium (step 701 of preparing the substrate in FIG. 7), step 902 of forming a first chemical conversion-treated layer (step 702 of forming the first chemical conversion-treated layer in FIG. 7), step 903 of forming a bending supplement layer (step 703 of forming the bending supplement layer in FIG. 7), step 904 of forming a color layer (step 704 of forming the color layer in FIG. 7), step 905 of forming a UV molding layer (step 705 of forming the UV molding layer in FIG. 7), step 906 of curing the UV molding layer (step 706 of curing the UV molding layer in FIG. 7), step 909 of cutting the substrate, step 910 of forming a second chemical conversion-treated layer, and step 911 of forming an electrodeposition coating layer.

According to an embodiment, step 909 of cutting the substrate may be performed through diamond cutting or CNC machining. As a CNC machining tool, a PCD or an MCD may be used, and machining may be performed for about 1 minute to 2 minutes.

According to an embodiment, after step 911 of forming the electrodeposition coating layer, a cleaning step (not shown) and a washing step (not shown) may be further performed. The cleaning step may be performed by dipping cleaning using an alcohol-containing cleaning solution at the temperature of 40° C. to 45° C. for 120 seconds or less. The washing step may be performed using distilled water.

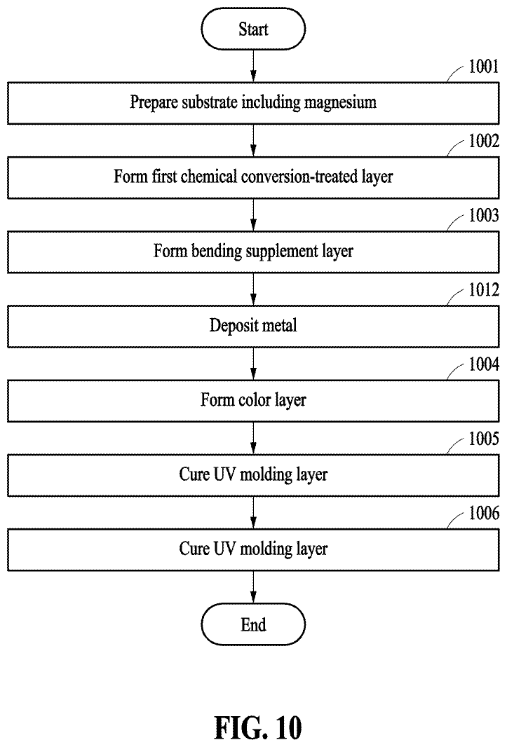

FIG. 10 is a flowchart illustrating a method of manufacturing an electronic device cover according to an embodiment.

Referring to FIG. 10, the method of manufacturing an electronic device cover may include step 1001 of preparing a substrate including magnesium (step 701 of preparing the substrate in FIG. 7), step 1002 of forming a first chemical conversion-treated layer (step 702 of forming the first chemical conversion-treated layer in FIG. 7), step 1003 of forming a bending supplement layer (step 703 of forming the bending supplement layer in FIG. 7), step 1012 of depositing a metal, step 1004 of forming a color layer (step 704 of forming the color layer in FIG. 7), step 1005 of forming a UV molding layer (step 705 of forming the UV molding layer in FIG. 7), step 1006 of curing the UV molding layer (step 706 of curing the UV molding layer in FIG. 7).

According to an embodiment, step 1012 of depositing the metal may be performed after step 1003 of forming the bending supplement layer, and may be performed through a physical vapor deposition (PVD) scheme. A metal deposition layer formed on the bending compensating layer may impart a metallic texture to the electronic device cover so that a user may be provided with an aesthetically pleasing effect while using an electronic device. A step of depositing a metal may be performed by depositing at least one metal selected from the group of tin (Sn), indium (In), aluminum (Al), and titanium (Ti) on the bending supplement layer through a physical vapor deposition scheme.

According to an embodiment, a step of forming a first chemical conversion-treated layer (e.g., step 702 of forming the first chemical conversion-treated layer in FIG. 7) may be performed using a chromate compound including at least one selected from the group of sodium chromate (Na₂CrO₄), potassium chromate (K₂CrO₄), ammonium chromate ((NH₄)₂CrO₄), calcium chromate (CaCrO₄), zinc chromate (ZnCrO₄), sodium dichromate (Na₂Cr₂O₇), potassium dichromate (K₂Cr₂O₇), and ammonium dichromate ((NH₄)₂Cr₂O₇), or using micro arc oxidation (MAO).

According to an embodiment, after a curing step (e.g., step 806 of curing the UV molding layer in FIG. 8), a step (e.g., step 807 of deforming the shape of the substrate on which the UV molding layer is formed in FIG. 8) of deforming the shape of the substrate on which the UV molding layer is formed and a step (e.g., step 808 of secondarily curing the UV molding layer in FIG. 8) of secondarily curing (re-curing) the UV molding layer may be further included.

According to an embodiment, the step (e.g., step 807 of deforming the shape of the substrate on which the UV molding layer is formed in FIG. 8) of deforming the shape of the substrate may include bending the substrate by dividing the bending of the substrate into at least three operations so that a radius of curvature is less than 1.0 mm.

According to an embodiment, the step (e.g., step 807 of deforming the shape of the substrate on which the UV molding layer is formed in FIG. 8) of deforming the shape of the substrate may be performed around a reference line spaced apart by a distance of 3 mm or greater from an outermost periphery of the substrate.

According to an embodiment, after a curing step (e.g., step 906 of curing the UV molding layer in FIG. 9), a step (e.g., step 909 of cutting the substrate in FIG. 9) of cutting the substrate, a step (e.g., step 910 of forming the second chemical conversion-treated layer in FIG. 9) of forming a second chemical conversion-treated layer on a cut portion formed by cutting the substrate, and a step (e.g., step 911 of forming the electrodeposition coating layer in FIG. 9) of forming an electrodeposition coating layer on the second chemical conversion-treated layer may be further included.

According to an embodiment, after a step (e.g., step 1003 of forming the bending supplement layer 1003 in FIG. 10) of forming a bending supplement layer, a step (e.g., step 1012 of depositing the metal in FIG. 10) of depositing a metal by a physical vapor deposition (PVD) scheme may be further included.

According to an embodiment, a step (e.g., step 705 of forming the UV molding layer in FIG. 7) of forming a UV molding layer may include a formation of a pattern.

The electronic device according to various embodiments disclosed herein may be one of various types of electronic devices. The electronic device may include, for example, a portable communication device (e.g., a smartphone), a computer device, a portable multimedia device, a portable medical device, a camera, a wearable device, or a home appliance device. According to an embodiment of the disclosure, the electronic device is not limited to those described above.

The various embodiments of the present disclosure and the terms used therein are not intended to limit the technological features set forth herein to particular embodiments and include various changes, equivalents, or replacements for a corresponding embodiment. In connection with the description of the drawings, like reference numerals may be used for similar or related components. It is to be understood that a singular form of a noun corresponding to an item may include one or more of the things, unless the relevant context clearly indicates otherwise. As used herein, “A or B”, “at least one of A and B”, “at least one of A or B”, “A, B or C”, “at least one of A, B and C”, and “at least one of A, B, or C”, each of which may include any one of the items listed together in the corresponding one of the phrases, or all possible combinations thereof. Terms such as “1st”, “2nd”, or “first” or “second” may simply be used to distinguish the component from other components in question, and do not limit the components in other aspects (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., by wire), wirelessly, or via a third element.

As used in connection with various embodiments of the disclosure, the term “module” may include a unit implemented in hardware, software, or firmware, and may interchangeably be used with other terms, for example, “logic”, “logic block”, “part”, or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., an internal memory 136 or an external memory 138) that is readable by a machine (e.g., the electronic device 101). For example, a processor (e.g., the processor 120) of the machine (e.g., the electronic device 101) may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments disclosed herein may be included and provided in a computer program product. The computer program product may be traded as a product between a seller and a buyer. The computer program product may be distributed in the form of a machine-readable storage medium (e.g., compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as a memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device cover having a layered structure, the electronic device cover comprising:
a substrate comprising magnesium;
a first chemical conversion-treated layer disposed on the substrate;
a bending supplement layer disposed on the first chemical conversion-treated layer;
a color layer disposed on the bending supplement layer; and
an ultraviolet (UV) molding layer disposed on the color layer.

2. The electronic device cover of claim 1, wherein the bending supplement layer comprises an epoxy-based polymer.

3. The electronic device cover of claim 1, further comprising:
a metal deposition layer disposed between the bending supplement layer and the color layer,
wherein the metal deposition layer comprises at least one metal selected from the group consisting of tin (Sn), indium (In), aluminum (Al), and titanium (Ti).

4. The electronic device cover of claim 1, wherein the UV molding layer comprises at least one bifunctional monomer selected from the group consisting of hexanediol diacrylate (HDDA), tripropylene glycol diacrylate (TPGDA), hydroxypropyl acrylate (HPA), and 2-hydroxyethyl methacrylate (2-HEMA).

5. The electronic device cover of claim 1, wherein the UV molding layer has hardness of a pencil hardness of F or higher.

6. The electronic device cover of claim 1, wherein the first chemical conversion-treated layer comprises at least one selected from the group consisting of magnesium chromate, magnesium oxide, aluminum oxide, silicon oxide, and titanium oxide.

7. The electronic device cover of claim 1, wherein the bending supplement layer and the UV molding layer are crack-free.

8. The electronic device cover of claim 1, wherein at least one area of the UV molding layer comprises a pattern.

9. The electronic device cover of claim 1, further comprising:
a cut portion; and
a second chemical conversion-treated layer disposed on the cut portion; and
an electrodeposition coating layer disposed on the second chemical conversion-treated layer,
wherein the second chemical conversion-treated layer comprises zirconium, and
wherein the electrodeposition coating layer is formed with a thickness of 10 μm to 20 μm.

10. A method of manufacturing an electronic device cover having a layered structure, the method comprising:
preparing a substrate comprising magnesium;
forming a first chemical conversion-treated layer on the substrate;
forming a bending supplement layer on the first chemical conversion-treated layer;
forming a color layer on the bending supplement layer;
forming an ultraviolet (UV) molding layer on the color layer; and
curing the UV molding layer.

11. The method of claim 10, wherein forming the first chemical conversion-treated layer is performed using:
a chromate compound comprising at least one selected from the group consisting of sodium chromate (Na₂CrO₄), potassium chromate (K₂CrO₄), ammonium chromate ((NH₄)₂CrO₄), calcium chromate (CaCrO₄), zinc chromate (ZnCrO₄), sodium dichromate (Na₂Cr₂O₇), potassium dichromate (K₂Cr₂O₇), and ammonium dichromate ((NH₄)₂Cr₂O₇); or
micro arc oxidation (MAO).

12. The method of claim 10, further comprising:
after curing the UV molding layer,
deforming a shape of the substrate on which the UV molding layer is formed; and
re-curing the UV molding layer,
wherein deforming the shape of the substrate comprises bending the substrate by dividing the bending of the substrate into at least three operations so that a radius of curvature is less than 1.0 mm, and
wherein deforming the shape of the substrate is performed around a reference line spaced apart by a distance of 3 mm or greater from an outermost periphery of the substrate.

13. The method of claim 10, further comprising:
after curing the UV molding layer,
cutting the substrate;
forming a second chemical conversion-treated layer on a cut portion formed by cutting the substrate; and
forming an electrodeposition coating layer on the second chemical conversion-treated layer.

14. The method of claim 10, further comprising:
after forming the bending supplement layer,
depositing a metal by a physical vapor deposition (PVD) scheme.

15. The method of claim 10, wherein the forming the UV molding layer comprises a formation of a pattern.
